(19) United States
(12) Patent Application Publication
(10) Pub. No.: US 2024/0290889 A1
(43) Pub. Date: Aug. 29, 2024

(54) DISPLAY PANEL, MANUFACTURING METHOD THEREOF, AND DISPLAY DEVICE

(71) Applicant: Shenzhen China Star Optoelectronics Semiconductor Display Technology Co., Ltd., Shenzhen, Guangdong (CN)

(72) Inventor: Macai LU, Shenzhen, Guangdong (CN)

(73) Assignee: Shenzhen China Star Optoelectronics Semiconductor Display Technology Co., Ltd., Shenzhen, Guangdong (CN)

(21) Appl. No.: 17/292,861

(22) PCT Filed: Mar. 31, 2021
(86) PCT No.: PCT/CN2021/084525

§ 371 Date: May 12, 2024

(30) Foreign Application Priority Data
Feb. 4, 2021 (CN) 202110156323.X

(51) Int. Cl. H01L 29/786; H01L 29/66; H10K 59/12; H10K 59/126; H10K 59/80

(52) U.S. Cl. CPC H01L 29/78633; H01L 29/6675; H10K 59/1201; H10K 59/126; H10K 59/8792

(57) ABSTRACT

The present disclosure provides a display panel, a manufacturing method thereof, and a display device. The display panel includes a substrate and a thin film transistor layer disposed on the substrate, wherein the thin film transistor layer includes an active layer, a metal layer, and an anti-reflection layer; the anti-reflection layer is at least disposed on a side of the metal layer close to the active layer, and a reflectivity of the anti-reflection layer is less than a reflectivity of the metal layer.

### BACKGROUND OF INVENTION

### Field of Invention

The present disclosure relates to the field of display technology, in particular to the manufacture of display devices, and in particular to a display panel, a manufacturing method thereof, and a display device.

### Description of Prior Art

An oxide semiconductor thin film transistor uses oxide as an electron channel, which has higher mobility, smaller parasitic capacitance, and lower leakage current than a polysilicon thin film transistor.

However, an active layer in the oxide semiconductor thin film transistor is greatly affected by light, which causes the oxide semiconductor thin film transistor to easily change in performance and fail under the light, thus reducing stability and reliability of the oxide semiconductor thin film transistor.

### SUMMARY OF INVENTION

### Technical Problem

An object of the present disclosure is to provide a display panel, a manufacturing method thereof, and a display device, so as to reduce the light irradiated to an active layer and solve the problem that the oxide semiconductor thin film transistor fails due to the performance change of the oxide semiconductor thin film transistor caused by the active layer being irradiated by incident light in the prior art.

### Problem Solution

### Technical Solution

An embodiment of the present disclosure provides a display panel, and the display panel includes:
a substrate; and
a thin film transistor layer, wherein the thin film transistor layer is disposed on the substrate, the thin film transistor layer includes an active layer, a metal layer and an anti-reflection layer, the anti-reflection layer is at least disposed on a side of the metal layer close to the active layer, and a reflectivity of the anti-reflection layer is less than a reflectivity of the metal layer.

In an embodiment, the metal layer includes a light-shielding layer, the light-shielding layer is disposed on a side of the active layer close to the substrate, the anti-reflection layer includes a first anti-reflection layer, the first anti-reflection layer is disposed on a side of the light-shielding layer close to the active layer, and a reflectivity of the first anti-reflection layer is less than a reflectivity of the light-shielding layer.

In an embodiment, a material of the first anti-reflection layer includes molybdenum oxide.

In an embodiment, the first anti-reflection layer includes:
a first sub-layer, wherein a material of the first sub-layer includes molybdenum-titanium alloy doped with nickel, molybdenum-titanium alloy, or molybdenum; and
a second sub-layer, wherein the second sub-layer is disposed on a side of the first sub-layer close to the active layer, and a material of the second sub-layer includes indium zinc oxide.

In an embodiment, a material of the light-shielding layer includes metal.

In an embodiment, the display panel further includes a buffer layer disposed on a side of the first anti-reflection layer away from the substrate, wherein the buffer layer covers the first anti-reflection layer and the substrate.

In an embodiment, the metal layer includes a gate layer, the gate layer is disposed on a side of the active layer away from the substrate, the anti-reflection layer further includes a second anti-reflection layer, the second anti-reflection layer is disposed on a side of the gate layer close to the active layer, and a reflectivity of the second anti-reflection layer is less than a reflectivity of the gate layer.

In an embodiment, a material of the second anti-reflection layer includes molybdenum oxide.

In an embodiment, the second anti-reflection layer includes:
a third sub-layer, wherein a material of the third sub-layer includes molybdenum-titanium alloy doped with nickel, molybdenum-titanium alloy, or molybdenum; and
a fourth sub-layer, wherein the fourth sub-layer is disposed on a side of the third sub-layer close to the active layer, and a material of the fourth sub-layer includes indium zinc oxide.

In an embodiment, a material of the gate layer includes metal.

In an embodiment, the thin film transistor layer further includes an insulating layer disposed between the gate layer and the active layer.

In an embodiment, a material of the active layer includes metal oxide.

In an embodiment, the anti-reflection layer is disposed opposite to the active layer, and two opposite ends of the anti-reflection layer extend beyond two opposite ends of the active layer.

Another embodiment of the present disclosure provides a method of manufacturing a display panel for manufacturing the display panel as described above, and the method includes:
providing a substrate; and
forming a thin film transistor layer on the substrate, wherein the thin film transistor layer includes an active layer, a metal layer, and an anti-reflection layer, the anti-reflection layer is disposed at least on a side of the metal layer close to the active layer, and a reflectivity of the anti-reflection layer is less than a reflectivity of the metal layer.

In an embodiment, the metal layer includes a light-shielding layer, the anti-reflection layer includes a first anti-reflection layer, and the step of forming the thin film transistor layer on the substrate includes:
forming the light-shielding layer on the substrate;
forming the first anti-reflection layer on the light-shielding layer, wherein a reflectivity of the first anti-reflection layer is less than a reflectivity of the light-shielding layer; and forming the active layer on the first anti-reflection layer.

In an embodiment, the metal layer further includes a gate layer, the anti-reflection layer further includes a second anti-reflection layer, and after forming the active layer on the first anti-reflection layer, the method further includes:
forming the second anti-reflection layer on the active layer; and
forming the gate layer on the second anti-reflection layer, wherein a reflectivity of the second anti-reflection layer is less than a reflectivity of the gate layer.

In an embodiment, the metal layer includes a gate layer, the anti-reflection layer further includes a second anti-reflection layer, and the step of forming a thin film transistor layer on the substrate includes:
forming the active layer on the substrate;
forming the second anti-reflection layer on the active layer; and
forming the gate layer on the second anti-reflection layer, wherein a reflectivity of the second anti-reflection layer is less than a reflectivity of the gate layer.

In an embodiment, after the step of forming the gate layer on the second anti-reflection layer, wherein the reflectivity of the second anti-reflection layer is less than the reflectivity of the gate layer, or after the step of forming the gate layer on the second anti-reflection layer, wherein the reflectivity of the second anti-reflection layer is less than the reflectivity of the gate layer, and the method further includes:
forming an intermediate dielectric layer on the gate layer;
forming a source layer, a drain layer and a second conductive layer on the intermediate dielectric layer;
forming a passivation layer on the intermediate dielectric layer, the drain layer and part of the source layer; forming a black light-shielding layer on the passivation layer; and
forming a light-emitting layer, a first electrode, and a second electrode on the source layer and the second conductive layer.

Still another embodiment of the present disclosure provides a display device, which includes a display panel as described above or a display panel manufactured by any method described above.

### Beneficial Effects of Invention

### Beneficial Effects

The present disclosure provides a display panel, a manufacturing method thereof, and a display device. The display panel includes a thin film transistor layer. The thin film transistor layer includes an active layer, a metal layer, and an anti-reflection layer. By disposing the anti-reflection layer on a side of the metal layer close to the active layer, and the reflectivity of the anti-reflection layer being less than the reflectivity of the metal layer, that is, the anti-reflection layer can enhance light absorption at a side of the metal layer close to the active layer, thus reducing the light irradiated on the active layer, so that the risk of failure due to performance changes of the thin film transistor layer is reduced, thereby improving the stability and reliability of the thin film transistor layer.

### BRIEF DESCRIPTION OF DRAWINGS

### Description of Drawings

The following detailed description of specific implementations of the present application in conjunction with the accompanying drawings will make the technical solutions and other beneficial effects of the present application obvious.

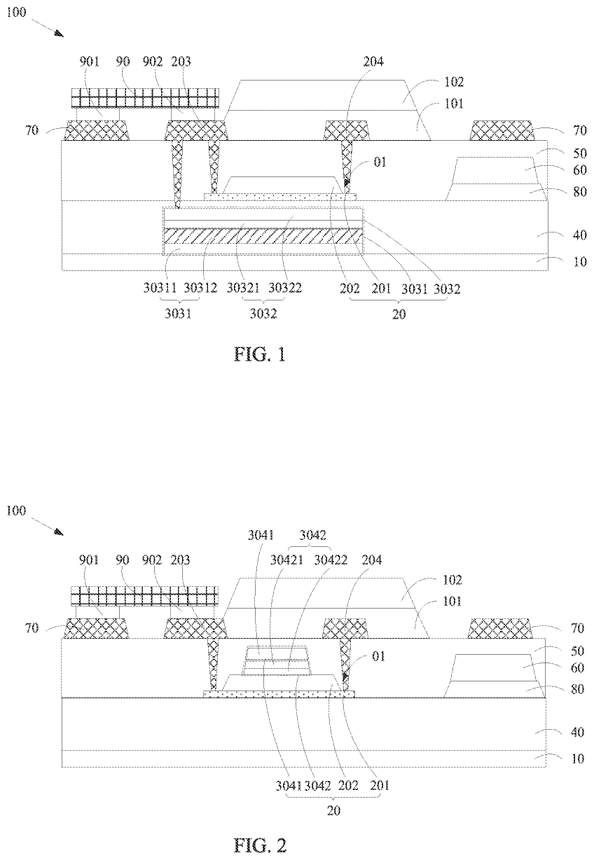

FIG. 1 is a schematic cross-sectional view of a display panel provided by an embodiment of the present disclosure.

FIG. 2 is a schematic cross-sectional view of another display panel provided by an embodiment of the present disclosure.

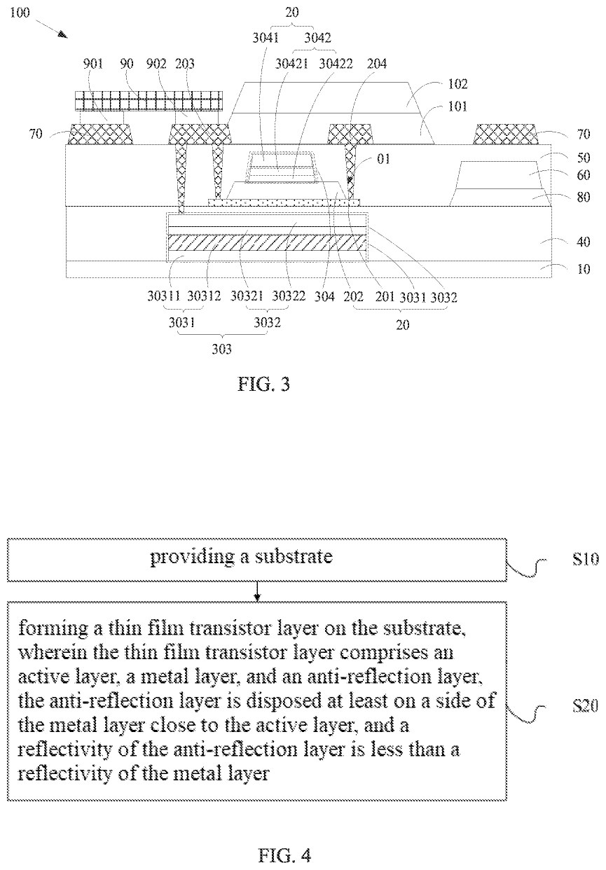

FIG. 3 is a schematic cross-sectional view of further another display panel provided by an embodiment of the present disclosure.

FIG. 4 is a flowchart of a first method of manufacturing a display panel provided by an embodiment of the present disclosure.

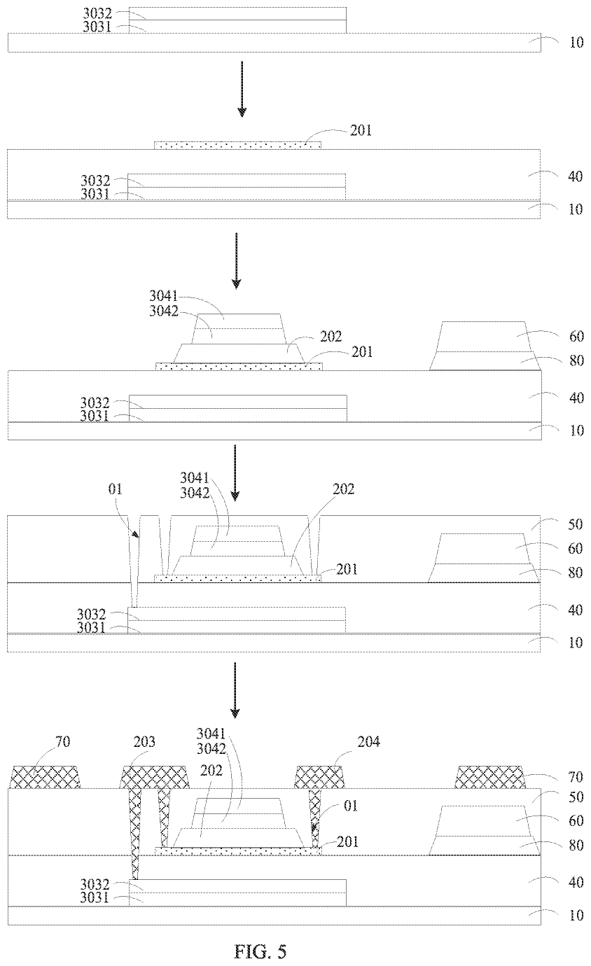

FIG. 5 is a schematic diagram of a process scheme of a method of manufacturing a display panel according to an embodiment of the present disclosure.

FIG. 6 is a flowchart of a second method of manufacturing a display panel according to an embodiment of the present disclosure.

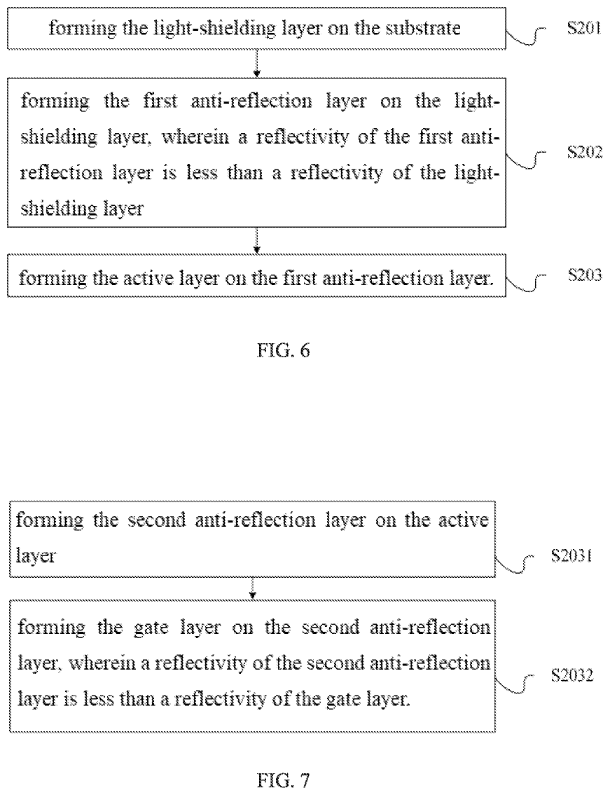

FIG. 7 is a flowchart of a third method of manufacturing a display panel provided by an embodiment of the present disclosure.

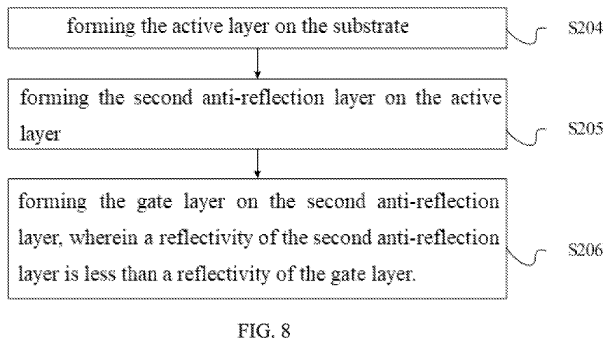

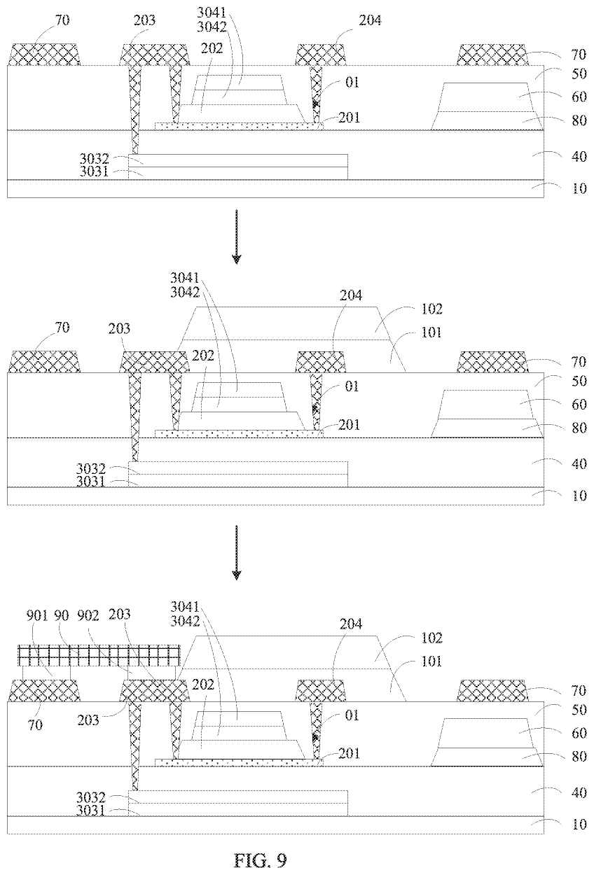

FIG. 8 is a flowchart of a fourth method of manufacturing a display panel according to an embodiment of the present disclosure.

FIG. 9 is a schematic diagram of a process scheme of another method of manufacturing a display panel according to an embodiment of the present disclosure.

### DETAILED DESCRIPTION OF PREFERRED EMBODIMENTS

### Implementation of the Present Invention

The technical solutions in the embodiments of the present disclosure will be clearly and completely described below in conjunction with the accompanying drawings in the embodiments of the present disclosure. Obviously, the described embodiments are only a part of the embodiments of the present disclosure, rather than all the embodiments. Based on the embodiments of the present disclosure, all other embodiments obtained by those skilled in the art without creative work shall fall within the protection scope of the present disclosure.

In the description of the present disclosure, it should be understood that the orientation or positional relationship indicated by the terms “upper”, “lower”, “near”, “far away”, etc. are based on the orientation or positional relationship shown in the drawings, for example, “upper” only refers to a surface above the object, specifically refers to directly above, obliquely above, or the upper surface, as long as it is above the level of the object; “both sides” or “two opposite ends” refer to the objects that can be shown in the figure The two positions can be in direct or indirect contact with the object. The above orientation or positional relationship is only for the convenience of describing the present invention and simplifying the description, rather than indicating or implying that the device or element referred to must have a specific orientation, be constructed and operated in a specific orientation. Therefore, it cannot be understood as a limitation of the present disclosure.

In addition, it should be noted that the drawings provide only the structures and steps closely related to the present disclosure, and omit some details that are not relevant to the present disclosure. The purpose is to simplify the drawings so that the inventive features are clear at a glance, and it does mean the actual device and method are exactly the same as the drawings, and the drawings should be not considered as a limitation of the actual device and method.

The present disclosure provides a display panel. The display panel includes, but is not limited to, the following embodiments and a combination of the following embodiments.

In an embodiment, as shown in FIG. 1 to FIG. 3, the display panel 100 includes: a substrate 10; a thin film transistor layer 20 located on the substrate 10, wherein the thin film transistor layer 20 includes: an active layer 201, a metal layer, and an anti-reflection layer located at least on a side of the metal layer close to the active layer 201, wherein the reflectivity of the anti-reflection layer is less than that of the metal layer. It should be noted that the metal layer may include, but is not limited to, two separately arranged layers, the anti-reflection layer may also include, but is not limited to, two separately arranged layers, and the plurality of the layers in the anti-reflection layer are in one-to-one correspondence with the plurality of the layers in the metal layer, and satisfy that the reflectivity of each of the layers in the anti-reflection layer is less than the reflectivity of its corresponding one of the layers in the metal layer.

The substrate 10 may be a rigid substrate or a flexible substrate, the rigid substrate may be glass or a silicon wafer, and the materials of the rigid substrate may include, but are not limited to, at least one of quartz powder, strontium carbonate, barium carbonate, boric acid, and boric anhydride, aluminum oxide, calcium carbonate, barium nitrate, magnesium oxide, tin oxide, or zinc oxide. The flexible substrate may be a polymer material substrate, a metal foil substrate, an ultra-thin glass substrate, a polymer/inorganic substrate, or a polymer/organic/inorganic substrate, wherein the polymer material may include at least one of polyethylene, polypropylene, polystyrene, polyethylene terephthalate, polyethylene terephthalate, or polyimide.

In particular, the material of the active layer 201 includes metal oxide. Specifically, the material of the active layer 201 may include indium gallium zinc oxide, indium gallium tin oxide, indium gallium oxide, indium zinc oxide, aluminum indium zinc oxide, indium gallium zinc tin oxide, or other metal oxides. Further, the material of the active layer 201 may include amorphous metal oxide. It can be understood that the thin film transistor layer 20 prepared by using the active layer 201 in this embodiment has higher mobility, smaller parasitic capacitance, and lower leakage current than a traditional amorphous silicon thin film transistor. Further, the thin film transistor layer 20 can be used as a current-driving display circuit. For example, the light-emitting device in the display panel 100 may include an organic light-emitting semiconductor light-emitting device, a micro light-emitting diode, or other self-luminous devices.

Specifically, the anti-reflection layer and the active layer 201 are arranged opposite to each other, and the two opposite ends of the anti-reflection layer respectively extend beyond the two opposite ends of the active layer 201 to ensure that the active layer 201 is shielded. It is appreciated that since the anti-reflection layer is located on the side of the corresponding metal layer close to the active layer 201, and the reflectivity of the anti-reflection layer is less than the reflectivity of the corresponding metal layer, that is, the light reaching the surface of the anti-reflection layer can be absorbed to a greater extent than the light irradiating the surface of the metal layer, the light reflected to the active layer 201 can be reduced, and a risk of failure due to performance changes of the thin film transistor layer can be reduced, thereby improving the stability and reliability of the operation of the thin film transistor layer 20.

In an embodiment, as shown in FIG. 1 and FIG. 3, the metal layer includes a light-shielding layer 3031, the light-shielding layer 303 is located on the side of the active layer 201 close to the substrate 10, and the anti-reflection layer includes a first anti-reflection layer 3032 located on a side of the light-shielding layer 3031 close to the active layer 201, and the reflectivity of the first anti-reflection layer 3032 is less than the reflectivity of the light-shielding layer 3031. It should be noted that since the light-shielding layer 3031 is closer to the substrate 10, and the first anti-reflection layer 3032 is closer to the active layer 201, external light or backlight light can pass through the light-shielding layer 3031 and the first anti-reflection layer 3032 in sequence. It is appreciated that setting the reflectivity of the light-shielding layer 3031 to be relative large can not only reflect more external light or backlight light to the side away from the active layer 201, so as to improve the utilization of light, but also reduce a passing rate of light through the light-shielding layer 3031, so as to prevent light from irradiating the active layer 201; and setting the reflectivity of the first anti-reflection layer 3032 to be relatively small can absorb most of the light irradiated to the first anti-reflection layer 3032, thereby reducing the light reflected from the first anti-reflection layer 3032 to the active layer 201. Therefore, this embodiment can reduce the light irradiated on the active layer 201, reduce risk of failure due to performance changes of the thin film transistor layer 20, so as to improve the stability and reliability of the thin film transistor layer 20 in operation.

In an embodiment, the material of the light-shielding layer 3031 includes a metal material. Specifically, the light-shielding layer 3031 may be a single layer or a composite layer. For example, when the light-shielding layer 3031 is single-layered, the material of the light-shielding layer 3031 may include, but is not limited to, copper or aluminum. When the light-shielding layer 3031 is a composite layer, as shown in FIG. 1 and FIG. 3, the light-shielding layer 3031 includes a first light-shielding layer 30311 and a second light-shielding layer 30312 located on a side of the first light-shielding layer 30311 away from the substrate 10. The material of the first light-shielding layer 30311 may include, but is not limited to, molybdenum, molybdenum-titanium alloy, or molybdenum-titanium alloy doped with nickel; and the material of the second light-shielding layer 30312 may include, but is not limited to, copper or aluminum. The first light-shielding layer 30311 is configured to increase adhesion between the light-shielding layer 3031 and the substrate 10.

In an embodiment, the material of the first anti-reflection layer 3032 includes molybdenum oxide. Specifically, when the first anti-reflection layer 3032 is a single layer, the material of the first anti-reflection layer 3032 may include molybdenum oxide. In an embodiment, as shown in FIG. 1 and FIG. 3, when the first anti-reflection layer 3032 is a composite layer, the first anti-reflection layer 3032 includes a first sub-layer 30321 made of a material including, but not limited to, molybdenum-titanium alloy doped with nickel, molybdenum-titanium alloy, or molybdenum; and a second sub-layer 30322 located at a side of the first sub-layer 30321 close to the active layer 201 and made of a material including, but not limited to, indium zinc oxide or indium tin oxide.

Further, as shown in FIG. 1 to FIG. 3, the display panel 100 further includes a buffer layer 40 located on a side of the first anti-reflection layer 3032 away from the substrate 10, and the buffer layer 40 covers the first anti-reflection layer 3032 and the substrate 10. Specifically, the buffer layer 40 is insulative and may be a single layer or a composite layer. For example, when the buffer layer 40 is a single layer, the material of the buffer layer 40 may include, but is not limited to, silicon oxide, silicon nitride, or silicon oxynitride; and when the buffer layer 40 is a composite layer, the buffer layer 40 may include a first buffer layer and a second buffer layer located on a side of the first buffer layer away from the substrate 10, and the material of the first buffer layer may include, but is not limited to, silicon nitride, and the material of the second buffer layer may include, but is not limited to, silicon oxide.

In an embodiment, as shown in FIG. 2 and FIG. 3, the metal layer includes a gate layer 3041, and the gate layer 3041 is located on the side of the active layer 201 away from the substrate 10, and the anti-reflection layer includes a second anti-reflection layer 3042 located at a side of the gate layer 3041 close to the active layer 201. The reflectivity of the second anti-reflection layer 3042 is less than that of the reflectivity of the gate layer 3041. Further, the gate layer 3041 is located on a side of the active layer 201 away from the substrate 10. Similarly, because the second anti-reflection layer 3042 is closer to the active layer 201, that is, external light passes through the gate layer 3041 and the second anti-reflection layer 3042 sequentially, setting the reflectivity of the second anti-reflection layer 3042 to be relatively small can absorb most of the light irradiated to the second anti-reflection layer 3042, and reduce the light reflected from the second anti-reflection layer 3042 to the active layer 201. Therefore, in this embodiment, the light irradiated on the active layer 201 can be reduced, thereby reducing the risk of failure due to performance changes of the thin film transistor layer, so as to improve the stability and reliability of the thin film transistor layer 20 in operation.

In an embodiment, as shown in FIG. 2 and FIG. 3, the material of the gate layer 3041 includes a metal material. Specifically, the gate layer 3041 may be a single layer or a composite layer. When the gate layer 3041 is a single layer, as shown in FIG. 2 and FIG. 3, the material of the gate layer 3041 may include, but is not limited to, copper, aluminum, molybdenum, or titanium. Of course, the material of the gate layer 3041 may also include metal oxide, metal nitride, or metal oxynitride. When the gate layer 3041 is a composite layer, the material of the gate layer 3041 may include, but is not limited to, a molybdenum/aluminum/molybdenum layer, an aluminum/molybdenum layer, a molybdenum/copper layer, or a molybdenum-titanium alloy/copper layer.

In an embodiment, the material of the second anti-reflection layer 3042 includes molybdenum oxide. Specifically, when the second anti-reflection layer 3042 is a single layer, the material of the second anti-reflection layer 3042 may include molybdenum oxide. In an embodiment, as shown in FIG. 2 and FIG. 3, when the second anti-reflection layer 3042 is a composite layer, the second anti-reflection layer 3042 includes: a third sub-layer 30421 made of a material including, but not limited to, molybdenum-titanium alloy doped with nickel, molybdenum-titanium alloy, or molybdenum; and a fourth sub-layer 30422 located at a side of the third sub-layer 30421 close to the active layer 201 and made of a material including, but not limited to, indium zinc oxide, or indium tin oxide.

Further, as shown in FIG. 1 to FIG. 3, the thin film transistor layer 20 further includes an insulating layer 202 located between the gate layer 3041 and the active layer 201. Specifically, the insulating layer 202 may be a single layer or a composite layer. When the insulating layer 202 is a single layer, as shown in FIG. 1 to FIG. 3, the material of the insulating layer 202 may include, but is not limited to, silicon oxide or silicon nitride; when the insulating layer 202 is a composite layer, the insulating layer 202 can be, but not limited to, aluminum oxide/silicon nitride/silicon oxide layer, silicon oxide/nitride silicon/silicon oxide layer.

Specifically, as shown in FIG. 1 to FIG. 3, the display panel 100 further includes an intermediate dielectric layer 50 that covers the gate layer 3041, the buffer layer 40, the active layer 201, and the insulating layer 202. The intermediate dielectric layer 50 is provided with a plurality of through holes 01; further, the thin film transistor layer 20 also includes a source layer 203 and a drain layer 204, as shown in FIG. 1 and FIG. 3, two opposite ends of the source layer 203 are respectively connected to a left end of the active layer 201 and the light-shielding layer 3031 through their corresponding through holes 01, and the drain layer 204 is connected to a right end of the active layer 201 through its corresponding through hole 01. Specifically, the material of the intermediate dielectric layer 50 may include, but is not limited to, silicon oxide, silicon nitride, or silicon oxynitride. Specifically, the source layer 203 and the drain layer 204 have the same film structure, and both may be single-layered or composite-layered. When the source layer 203 and the drain layer 204 are both single-layered, as shown in FIG. 1 to FIG. 3, the materials of the source layer 203 and the drain layer 204 may include, but are not limited to, molybdenum, aluminum, copper, titanium, indium tin oxide, or copper-niobium alloy. When the source layer 203 and the drain layer 204 are both composite layers, both the source layer 203 and the drain layer 204 can be, but not limited to, molybdenum/aluminum layers, molybdenum/copper layers, molybdenum/copper/indium zinc oxide layers, indium zinc oxide/copper/indium zinc oxide layers, molybdenum/copper/indium tin oxide layers, nickel/copper/nickel layers, molybdenum-nickel-titanium alloy/copper/molybdenum-nickel-titanium alloy layers, or nickel-chromium alloy/copper/nickel-chromium alloy layers.

Specifically, as shown in FIG. 1 to FIG. 3, the display panel 100 further includes a sub-insulating layer 80, a first conductive layer 60, and a second conductive layer 70. The sub-insulating layer 80 and the insulating layer 202 are in the same layer, and there is a gap between the sub-insulating layer 80 and the corresponding thin film transistor layer 20. The first conductive layer 60 and the gate layer 3041 are provided in the same layer, and there is a gap between the first conductive layer 60 and the corresponding thin film transistor layer 20. The second conductive layer 70, the source layer 203, and the drain layer 204 are arranged in the same layer, and there is a gap between the second conductive layer 70 and the corresponding thin film transistor layer 20. The sub-insulating layer 80 can be configured to elevate the first conductive layer 60, the first conductive layer 60 can be configured to transmit data signals, and the second conductive layer 70 can be configured to load high voltage or low voltage.

Specifically, as shown in FIG. 1 to FIG. 3, the display panel 100 further includes a light-emitting layer 90, a first electrode 901, and a second electrode 902. Two opposite ends of the light-emitting layer 90 close to a side of the thin film transistor layer 20 are respectively provided with the first electrode 901 and the second electrode 902. The first electrode 901 is connected to the light-emitting layer 90 and the corresponding second conductive layer 70, and the second electrode 902 is connected to the light-emitting layer 90 and the corresponding source layer 203. It is appreciated that because the second conductive layer 70 and the source layer 203 have different voltages, that is, the first electrode 901 and the second electrode 902 have a voltage difference, current will flow through the light-emitting layer 90, thus making the light-emitting layer 90 emit light. As described above, the light-emitting layer 90 may be, but is not limited to, an organic light-emitting semiconductor light-emitting device, a miniature light-emitting diode, or other self-luminous devices. Further, as shown in FIG. 1 to FIG. 3, the display panel 100 further includes a passivation layer 101 and a black light-shielding layer 102, wherein the passivation layer 101 covers the intermediate dielectric layer 50, the drain layer 204, and part of the source layer 203. The black light-shielding layer 102 is located at a side of the passivation layer 101 away from the thin film transistor layer 20. When the passivation layer 101 is a single layer, the material of the passivation layer 101 may include, but is not limited to, silicon oxide, silicon nitride, or silicon oxynitride. When the passivation layer 101 is a composite layer, it may be, but is not limited to, a silicon oxide/silicon nitride layer.

The present disclosure provides a method of manufacturing a display panel. The method of manufacturing the display panel includes, but is not limited to, the following embodiments and a combination of the following embodiments.

In an embodiment, as shown in FIG. 4 and FIG. 5, the method may include, but is not limited to, the following steps.

S10, providing a substrate.

As shown in FIG. 5, the substrate 10 may be a rigid substrate or a flexible substrate, the rigid substrate may be glass or a silicon wafer, and the materials of the rigid substrate may include, but are not limited to, at least one of quartz powder, strontium carbonate, barium carbonate, boric acid, and boric anhydride, aluminum oxide, calcium carbonate, barium nitrate, magnesium oxide, tin oxide, or zinc oxide. The flexible substrate may be a polymer material substrate, a metal foil substrate, an ultra-thin glass substrate, a polymer/inorganic substrate, or a polymer/organic/inorganic substrate, wherein the polymer material may include at least one of polyethylene, polypropylene, polystyrene, polyethylene terephthalate, polyethylene terephthalate, or polyimide.

S20, forming a thin film transistor layer on the substrate, wherein the thin film transistor layer includes an active layer, a metal layer, and an anti-reflection layer, the anti-reflection layer is disposed at least on a side of the metal layer close to the active layer, and a reflectivity of the anti-reflection layer is less than a reflectivity of the metal layer.

In particular, as shown in FIG. 5, the material of the active layer 201 includes metal oxide. Specifically, the material of the active layer 201 may include indium gallium zinc oxide, indium gallium tin oxide, indium gallium oxide, indium zinc oxide, aluminum indium zinc oxide, indium gallium zinc tin oxide, or others metal oxide. Further, the material of the active layer 201 may include amorphous metal oxide. It can be understood that the thin film transistor layer 20 prepared by using the active layer 201 in this embodiment has higher mobility, smaller parasitic capacitance, and lower leakage current than a traditional amorphous silicon thin film transistor. Further, the thin film transistor layer 20 can be used as a current-driving display circuit. For example, the light-emitting device in the display panel 100 may include an organic light-emitting semiconductor light-emitting device, a micro light-emitting diode, or other self-luminous devices.

Specifically, as shown in FIG. 5, the metal layer includes a light-shielding layer 3031, and the anti-reflection layer includes a first anti-reflection layer 3032. The light-shielding layer 3031 and the active layer 201 are arranged opposite to each other, and the two opposite ends of the light-shielding layer 3031 respectively extend beyond the two opposite ends of the active layer 201 to ensure that the active layer 201 is shielded. It is appreciated that since the first anti-reflection layer 3032 is located on the side of the light-shielding layer 3031 close to the active layer 201, and the reflectivity of the first anti-reflection layer 3032 is less than the reflectivity of the light-shielding layer 3031, that is, the light reaching the surface of the first anti-reflection layer 3032 can be absorbed to a greater extent than the light irradiating the surface of the light-shielding layer 3031, so that the light reflected to the active layer 201 can be reduced, and a risk of failure due to performance changes of the thin film transistor layer can be reduced, thereby improving the stability and reliability of the operation of the thin film transistor layer 20.

In an embodiment, as shown in FIG. 6, the step S20 may include, but is not limited to, the following steps.

S201, forming the light-shielding layer on the substrate.

In an embodiment, as shown in FIG. 5, the material of the light-shielding layer 3031 includes a metal material. Specifically, the light-shielding layer 3031 may be a single layer or a composite layer. For example, when the light-shielding layer 3031 is single-layered, the material of the light-shielding layer 3031 may include, but is not limited to, copper or aluminum. When the light-shielding layer 3031 is a composite layer, the light-shielding layer 3031 includes a first light-shielding layer and a second light-shielding layer located on a side of the first light-shielding layer away from the substrate 10. The material of the first light-shielding layer may include, but is not limited to, molybdenum, molybdenum-titanium alloy, or molybdenum-titanium alloy doped with nickel; the material of the second light-shielding layer may include, but is not limited to, copper or aluminum. The first light-shielding layer is configured to increase adhesion between the light-shielding layer 3031 and the substrates 10.

S202, forming the first anti-reflection layer on the light-shielding layer, wherein the reflectivity of the first anti-reflection layer is less than the reflectivity of the light-shielding layer.

In an embodiment, as shown in FIG. 5, the material of the first anti-reflection layer 3032 includes molybdenum oxide. Specifically, when the first anti-reflection layer 3032 is a single layer, the material of the first anti-reflection layer 3032 may include molybdenum oxide. In an embodiment, when the first anti-reflection layer 3032 is a composite layer, the first anti-reflection layer 3032 includes a first sub-layer made of a material including, but not limited to, molybdenum-titanium alloy doped with nickel, molybdenum-titanium alloy, or molybdenum; and a second sub-layer located at a side of the first sub-layer close to the active layer and made of a material including, but not limited to, indium zinc oxide or indium tin oxide.

Specifically, as shown in FIG. 5, a blanket light-shielding film and a blanket first anti-reflection film may be formed on the substrate 10 in sequence, and then the light-shielding film and the first anti-reflection film may be patterned at one time to form the light-shielding layer 3031 and the first anti-reflection layer 3032. Similarly, the light-shielding film and the first anti-reflection film may be blanketly formed and then patterned according to their actual layer structures.

S203, forming the active layer on the first anti-reflection layer.

It should be noted that, as shown in FIG. 5, since the light-shielding layer 3031 is closer to the substrate 10, and the first anti-reflection layer 3032 is closer to the active layer 201, that is, external light or backlight light passes through in sequence The light-shielding layer 3031 and the first anti-reflective layer 3032. It is appreciated that setting the reflectivity of the light-shielding layer 3031 to be relative large can not only reflect more external light or backlight light to the side away from the active layer 201, so as to improve the utilization of light, but also reduce a passing rate of light through the light-shielding layer 3031, so as to prevent light from irradiating the active layer 201; and setting the reflectivity of the first anti-reflection layer 3032 to be relatively small can absorb most of the light irradiated to the first anti-reflection layer 3032, thereby reducing the light reflected from the first anti-reflection layer 3032 to the active layer 201. Therefore, this embodiment can reduce the light irradiated on the active layer 201, reduce risk of failure due to performance changes of the thin film transistor layer, so as to improve the stability and reliability of the thin film transistor layer 20 in operation.

Further, as shown in FIG. 5, the display panel 100 further includes a buffer layer 40 located on a side of the light-shielding layer 3031 away from the substrate 10, and the buffer layer 40 covers the light-shielding layer 3031 and the substrate 10, that is, a blanket buffer layer 40 may be formed on the light-shielding layer 303 and the substrate 10 before the step S2031. Specifically, the buffer layer 40 is insulative and may be a single layer or a composite layer. For example, when the buffer layer 40 is a single layer, the material of the buffer layer 40 may include, but is not limited to, silicon oxide, silicon nitride, or silicon oxynitride; and when the buffer layer 40 is a composite layer, the buffer layer 40 may include a first buffer layer and a second buffer layer located on a side of the first buffer layer away from the substrate 10, and the material of the first buffer layer may include, but is not limited to, silicon nitride, and the material of the second buffer layer may include, but is not limited to, silicon oxide.

Similarly, a blanket active film may be formed on the buffer layer 40 first, and then the active film may be patterned to form the active layer 201. It should be noted that the active layer 201 and the light-shielding layer 3031 are arranged opposite to each other, and the two opposite ends of the active layer 201 do not exceed the two opposite ends of the light-shielding layer 3031, respectively.

In an embodiment, the metal layer further includes a gate layer, and the anti-reflection layer further includes a second anti-reflection layer. As shown in FIG. 7, the step S203 may include, but is not limited to, the following steps.

S2031, forming the second anti-reflection layer on the active layer.

Further, as shown in FIG. 5, the thin film transistor layer further includes an insulating layer 202 located between the gate layer 3041 and the active layer 201, that is, before the step S2031, the insulating layer 202 is first formed on the active layer 201. In view of above, the sub-insulating layer 80 can also be formed at the same time as the insulating layer 202 is formed. Specifically, the insulating layer 202 may be a single layer or a composite layer. When the insulating layer 202 is a single layer, the material of the insulating layer 202 may include, but is not limited to, silicon oxide or silicon nitride; and when the insulating layer 202 is a composite layer, the insulating layer 202 can be, but not limited to, aluminum oxide/silicon nitride/silicon oxide layer, silicon oxide/nitride silicon/silicon oxide layer. Similarly, a blanket insulating film can be formed on the active layer 201 first, and then the insulating film can be patterned to form the insulating layer 202.

In an embodiment, the material of the second anti-reflection layer 3042 includes molybdenum oxide. Specifically, when the second anti-reflection layer 3042 is a single layer, the material of the second anti-reflection layer 3042 may include molybdenum oxide. In an embodiment, when the second anti-reflection layer 3042 is a composite layer, the second anti-reflection layer 3042 includes: a third sub-layer, and the material of the third sub-layer includes, but is not limited to, molybdenum-titanium alloy doped with nickel, molybdenum-titanium alloy, or molybdenum; and a fourth sub-layer located on the side of the third sub-layer close to the active layer and made of a material including, but not limited to, indium zinc oxide or indium tin oxide.

S2032, forming the gate layer on the second anti-reflection layer, wherein a reflectivity of the second anti-reflection layer is less than a reflectivity of the gate layer.

In an embodiment, as shown in FIG. 5, the material of the gate layer 3041 includes a metal material. Specifically, the gate layer 3041 may be a single layer or a composite layer. When the gate layer 3041 is a single layer, the material of the gate layer 3041 may include, but is not limited to, copper, aluminum, molybdenum, or titanium. Of course, the material of the gate layer 3041 may also include metal oxide, metal nitride, or metal oxynitride. When the gate layer 3041 is a composite layer, the material of the gate layer 3041 may include, but is not limited to, a molybdenum/aluminum/molybdenum layer, an aluminum/molybdenum layer, a molybdenum/copper layer, or a molybdenum-titanium alloy/copper layer.

Similarly, a blanket second anti-reflection film and a blanket gate film can be formed on the insulating layer 202, the sub-insulating layer 80, the active layer 201, and the buffer layer 40 in sequence. The blanket second anti-reflection film and the gate film are patterned at one time to form the second anti-reflection layer 3042 and the gate layer 3041, and to form the first conductive layer 60 simultaneously. It is appreciated that the film structure of the first conductive layer 60 is the same as the film structure of the gate layer 304. Similarly, the second anti-reflection film and the gate film may be blanketly formed and then patterned according to their actual film structures.

In an embodiment, the metal layer includes a gate layer, and the anti-reflection layer includes a second anti-reflection layer. As shown in FIG. 8, the step S20 may also include, but is not limited to, the following steps.

S204, forming the active layer on the substrate.

Specifically, as shown in FIG. 5, details for the active layer 201 can be referred to the relevant description above. It is appreciated that the buffer layer 40 may be formed on the substrate 10 first, and then the active layer 201 may be formed on the buffer layer 40.

S205, forming the second anti-reflection layer on the active layer.

Specifically, details for the step S205 can be referred to the related description of the step S2031 described above.

S206, forming the gate layer on the second anti-reflection layer, wherein a reflectivity of the second anti-reflection layer is less than a reflectivity of the gate layer.

Specifically, details for the step S206 can be referred to the related description of the step S2032 described above.

In an embodiment, as shown in FIG. 9, after the step S2032 or the step S206, the following steps may be included, but not limited to.

S20321, forming an intermediate dielectric layer 50 on the gate layer 3041.

Specifically, according to the above discussion, the intermediate dielectric layer 50 is formed on the gate layer 304, the first conductive layer 60, the buffer layer 40, the active layer 201, and the insulating layer 202. The intermediate dielectric layer 50 is provided with a plurality of through holes 01, and the plurality of through holes 01 may be formed by patterning.

S20322, forming a source layer 203, a drain layer 204, and a second conductive layer 70 on the intermediate dielectric layer 50.

Specifically, details for the source layer 203, the drain layer 204, and the second conductive layer 70 can be referred to the relevant description above. Similarly, the source layer 203, the drain layer 204, and the second conductive layer 70 may be formed by patterning. Two opposite ends of the source layer 203 are respectively connected to a left end of the active layer 201 and the light-shielding layer 303, and the drain layer 204 is connected to a right end of the active layer 201.

S20323, forming a passivation layer 101 on the intermediate dielectric layer 50, the drain layer 204, and a part of the source layer 203, and forming a black light-shielding layer 102 on the passivation layer 101.

Specifically, details for the passivation layer 101 and the black light-shielding layer 102 can be referred to the relevant description above. A passivation film and a black light-shielding film can be formed on the intermediate dielectric layer 50, the drain layer 204, and a part of the source layer 203 in sequence, and then the black light-shielding film is patterned to form the black light-shielding layer 102; and then the passivation film is patterned to form the passivation layer 101 by using the black light-shielding layer 102 as a hard mask.

S20334, forming a light-emitting layer 90, a first electrode 901, and a second electrode 902 on the source layer 203 and the second conductive layer 70.

Specifically, details for the light-emitting layer 90, the first electrode 901, and the second electrode 902 may be referred to the relevant description above. The light-emitting layer 90, the first electrode 901, and the second electrode 902 can be fabricated first, and then transferred onto the corresponding source layer 203 and the corresponding second conductive layer 70 at one time.

An embodiment of the present disclosure provides a display device, and the display device includes any one of the display panels as described above or any one of the display panels manufactured by the method of manufacturing the display panel described above.

The present disclosure provides a display panel, a manufacturing method thereof, and a display device. The display panel includes a thin film transistor layer. The thin film transistor layer includes an active layer, a metal layer, and an anti-reflection layer. By disposing the anti-reflection layer on a side of the metal layer close to the active layer, and the reflectivity of the anti-reflection layer being less than the reflectivity of the metal layer, that is, the anti-reflection layer can enhance light absorption at a side of the metal layer close to the active layer, thus reducing the light irradiated on the active layer, so that the risk of failure due to performance changes of the thin film transistor layer is reduced, thereby improving the stability and reliability of the thin film transistor layer.

The display panel, the manufacturing method thereof, and the display device provided by the embodiments of the present invention have been described in detail above. Specific examples are used in this document to explain the principles and implementation of the present invention. The descriptions of the above embodiments are only for understanding the method of the present invention and its core idea; Meanwhile, for those skilled in the art, according to the idea of the present invention, there will be changes in the specific implementation and application scope. In summary, the content of this specification should not be construed as a limitation on the present invention.

1. A display panel, comprising:
a substrate; and
a thin film transistor layer, wherein the thin film transistor layer is disposed on the substrate, the thin film transistor layer comprises an active layer, a metal layer, and an anti-reflection layer, the anti-reflection layer is at least disposed on a side of the metal layer close to the active layer, and a reflectivity of the anti-reflection layer is less than a reflectivity of the metal layer.

2. The display panel according to claim 1, wherein the metal layer comprises a light-shielding layer, the light-shielding layer is disposed on a side of the active layer close to the substrate, the anti-reflection layer comprises a first anti-reflection layer, the first anti-reflection layer is disposed on a side of the light-shielding layer close to the active layer, and a reflectivity of the first anti-reflection layer is less than a reflectivity of the light shielding layer.

3. The display panel according to claim 2, wherein a material of the first anti-reflection layer comprises molybdenum oxide.

4. The display panel according to claim 2, wherein the first anti-reflection layer comprises:
a first sub-layer, wherein a material of the first sub-layer comprises molybdenum-titanium alloy doped with nickel, molybdenum-titanium alloy, or molybdenum; and
a second sub-layer, wherein the second sub-layer is disposed on a side of the first sub-layer close to the active layer, and a material of the second sub-layer comprises indium zinc oxide.

5. The display panel according to claim 2, wherein a material of the light shielding layer comprises metal.

6. The display panel according to claim 2, further comprising a buffer layer disposed on a side of the first anti-reflection layer away from the substrate, wherein the buffer layer covers the first anti-reflection layer and the substrate.

7. The display panel according to claim 1 or 2, wherein the metal layer comprises a gate layer, the gate layer is disposed on a side of the active layer away from the substrate, the anti-reflection layer further comprises a second anti-reflection layer, the second anti-reflection layer is disposed on a side of the gate layer close to the active layer, and a reflectivity of the second anti-reflection layer is less than a reflectivity of the gate layer.

8. The display panel according to claim 7, wherein a material of the second anti-reflection layer comprises molybdenum oxide.

9. The display panel according to claim 7, wherein the second anti-reflection layer comprises:
a third sub-layer, wherein a material of the third sub-layer comprises molybdenum-titanium alloy doped with nickel, molybdenum-titanium alloy, or molybdenum; and
a fourth sub-layer, wherein the fourth sub-layer is disposed on a side of the third sub-layer close to the active layer, and a material of the fourth sub-layer comprises indium zinc oxide.

10. The display panel according to claim 7, wherein a material of the gate layer comprises metal.

11. The display panel according to claim 7, wherein the thin film transistor layer further comprises an insulating layer disposed between the gate layer and the active layer.

12. The display panel according to claim 1, wherein a material of the active layer comprises metal oxide.

13. The display panel according to claim 1, wherein the anti-reflection layer is disposed opposite to the active layer, and two opposite ends of the anti-reflection layer extend beyond two opposite ends of the active layer.

14. A method of manufacturing a display panel, comprising:
providing a substrate; and
forming a thin film transistor layer on the substrate, wherein the thin film transistor layer comprises an active layer, a metal layer, and an anti-reflection layer, the anti-reflection layer is disposed at least on a side of the metal layer close to the active layer, and a reflectivity of the anti-reflection layer is less than a reflectivity of the metal layer.

15. The method of manufacturing the display panel according to claim 14, wherein the metal layer comprises a light-shielding layer, the anti-reflection layer comprises a first anti-reflection layer, and the step of forming the thin film transistor layer on the substrate comprises:
forming the light-shielding layer on the substrate;
forming the first anti-reflection layer on the light-shielding layer, wherein a reflectivity of the first anti-reflection layer is less than a reflectivity of the light-shielding layer; and
forming the active layer on the first anti-reflection layer.

16. The method of manufacturing the display panel according to claim 15, wherein the metal layer further comprises a gate layer, the anti-reflection layer further comprises a second anti-reflection layer, and after forming the active layer on the first anti-reflection layer, the method further comprises:
forming the second anti-reflection layer on the active layer; and
forming the gate layer on the second anti-reflection layer, wherein a reflectivity of the second anti-reflection layer is less than a reflectivity of the gate layer.

17. The method of manufacturing the display panel according to claim 15, wherein the metal layer comprises a gate layer, the anti-reflection layer further comprises a second anti-reflection layer, and the step of forming the thin film transistor layer on the substrate comprises:
forming the active layer on the substrate;
forming the second anti-reflection layer on the active layer; and
forming the gate layer on the second anti-reflection layer, wherein a reflectivity of the second anti-reflection layer is less than a reflectivity of the gate layer.

18. The method of manufacturing the display panel according to claim 16 or claim 17, wherein after the step of forming the gate layer on the second anti-reflection layer, wherein the reflectivity of the second anti-reflection layer is less than the reflectivity of the gate layer, or after the step of forming the gate layer on the second anti-reflection layer, wherein the reflectivity of the second anti-reflective layer is less than the reflectivity of the gate layer, and the method further comprises:
forming an intermediate dielectric layer on the gate layer;
forming a source layer, a drain layer, and a second conductive layer on the intermediate dielectric layer;
forming a passivation layer on the intermediate dielectric layer, the drain layer, and part of the source layer;
forming a black light shielding layer on the passivation layer; and
forming a light-emitting layer, a first electrode, and a second electrode on the source layer and the second conductive layer.

19. A display device, comprising the display panel of claim 1 or the display panel manufactured by the method of manufacturing the display panel of claim 14.
